(19) United States
(12) Patent Application Publication
(10) Pub. No.: US 2023/0402518 A1
(43) Pub. Date: Dec. 14, 2023

(54) INTEGRATED CIRCUIT DEVICE

(71) Applicant: Samsung Electronics Co., Ltd., Suwon-si (KR)

(72) Inventors: Taejin Park, Suwon-si (KR); Kyujin Kim, Suwon-si (KR); Bongsoo Kim, Suwon-si (KR); Huijung Kim, Suwon-si (KR); Pyung Moon, Suwon-si (KR); Chulkwon Park, Suwon-si (KR); Gyunghyun Yoon, Suwon-si (KR); Heejae Chae, Suwon-si (KR)

(21) Appl. No.: 18/202,085

(22) Filed: May 25, 2023

(30) Foreign Application Priority Data
Jun. 10, 2022 (KR) 10-2022-0071029

(51) Int. Cl. H01L 29/423; H10B 12/00; H01L 29/49

(52) U.S. Cl. CPC H01L 29/4236; H10B 12/315; H01L 29/4916

(57) ABSTRACT

An integrated circuit (IC) device includes a gate trench formed inside a substrate, the gate trench including a bottom portion and a sidewall portion, a gate electrode structure disposed apart from the bottom portion and the sidewall portion of the gate trench, the gate electrode structure including a gate electrode including a first sub-gate electrode formed in a lower portion of the gate trench and a second sub-gate electrode formed on the first sub-gate electrode and a gate capping layer formed on the second sub-gate electrode, and a gate insulating layer formed between the gate trench and the gate electrode structure, the gate insulating layer including a base insulating layer formed between the bottom portion and the sidewall portion of the gate trench and the gate electrode structure and a reinforcing insulating layer formed on a sidewall portion of the second sub-gate electrode.

### CROSS-REFERENCE TO RELATED APPLICATION

This application is based on and claims priority under 35 U.S.C. § 119 to Korean Patent Application No. 10-2022-0071029, filed on Jun. 10, 2022, in the Korean Intellectual Property Office, the disclosure of which is incorporated by reference herein in its entirety.

### BACKGROUND

Aspects of the inventive concept relate to an integrated circuit (IC) device, more particularly, to an IC device including a gate electrode structure and a gate insulating layer.

An IC device may include a gate electrode structure including a plurality of sub-gate electrodes and a gate insulating layer disposed on the gate electrode structure. As IC devices have become highly integrated, it is very important to improve the reliability of a gate insulating layer provided on a gate electrode structure. Degradation of the reliability of the gate insulating layer may lead to deterioration of the operating performance of the IC devices.

### SUMMARY

Aspects of the inventive concept provide an integrated circuit (IC) device in which the reliability of a gate insulating layer formed on a gate electrode structure including a plurality of sub-gate electrodes is improved.

According to an aspect of the inventive concept, there is provided an integrated circuit (IC) device including a gate trench formed inside a substrate, the gate trench including a bottom portion and a sidewall portion, a gate electrode structure disposed apart from the bottom portion and the sidewall portion of the gate trench, the gate electrode structure including a gate electrode including a first sub-gate electrode formed in a lower portion of the gate trench and a second sub-gate electrode formed on the first sub-gate electrode and a gate capping layer formed on the second sub-gate electrode, and a gate insulating layer formed between the gate trench and the gate electrode structure, the gate insulating layer including a base insulating layer formed between the bottom portion and the sidewall portion of the gate trench and the gate electrode structure and a reinforcing insulating layer formed on a sidewall portion of the second sub-gate electrode.

According to another aspect of the inventive concept, there is provided an integrated circuit (IC) device including a gate trench formed inside a substrate, the gate trench including a bottom portion and a sidewall portion, a gate electrode structure disposed apart from the bottom portion and the sidewall portion of the gate trench inside the gate trench, the gate electrode structure including a gate electrode including a first sub-gate electrode formed in a lower portion of the gate trench and a second sub-gate electrode formed on the first sub-gate electrode and a gate capping layer formed on the second sub-gate electrode, and a gate insulating layer formed between the gate trench and the gate electrode structure, the gate insulating layer including a base insulating layer formed between the bottom portion and the sidewall portion of the gate trench and the gate electrode structure and a reinforcing insulating layer formed on the sidewall portion of the second sub-gate electrode, wherein a second thickness of the gate insulating layer between the sidewall portion of the second sub-gate electrode and the sidewall of the gate trench on a top level of the second sub-gate electrode is greater than a first thickness of the gate insulating layer between the sidewall portion of the gate capping layer and the sidewall portion of the gate trench on a bottom level of the gate capping layer.

According to another aspect of the inventive concept, there is provided an integrated circuit (IC) device including a gate trench formed inside a substrate, the gate trench including a bottom portion and a sidewall portion, a gate electrode structure disposed apart from the bottom portion and the sidewall portion of the gate trench inside the gate trench, the gate electrode structure including a gate electrode including a first sub-gate electrode formed in a lower portion of the gate trench and including a metal layer and a second sub-gate electrode formed on the first sub-gate electrode and including a polysilicon layer doped with impurities and a gate capping layer formed on the second sub-gate electrode, and a gate insulating layer formed between the gate trench and the gate electrode structure, the gate insulating layer including a liner insulating layer formed on the bottom portion and the sidewall portion of the gate trench and including a silicon oxide layer, a base insulating layer formed between the liner insulating layer and the gate electrode structure and a reinforcing insulating layer formed on the sidewall portion of the second sub-gate electrode and including a silicon oxide layer, wherein a second thickness of the reinforcing insulating layer and the base insulating layer formed on the sidewall portion of the second sub-gate electrode on a top level of the second sub-gate electrode is greater than a first thickness of the base insulating layer formed on the sidewall portion of the gate capping layer on a bottom level of the gate capping layer.

### BRIEF DESCRIPTION OF THE DRAWINGS

Embodiments of the inventive concept will be more clearly understood from the following detailed description taken in conjunction with the accompanying drawings in which:

FIG. 1 is a layout view illustrating an integrated circuit (IC) device according to an embodiment;

FIG. 2 is a cross-sectional view taken along line A1-A1′ of FIG. 1;

FIG. 3 is an enlarged view of a portion of EL1 of FIG. 2;

FIG. 4 is a detailed view illustrating a gate structure of FIGS. 1 to 3;

FIG. 5 is an enlarged view of a portion of EL2 of FIG. 4;

FIG. 6 is an enlarged view of a gate structure of an IC device according to another embodiment;

FIG. 7 is a detailed view illustrating the gate structure of FIG. 6;

FIG. 8 is an enlarged view of a portion of EL2-1 of FIG. 7;

FIG. 9 is an enlarged view of a gate structure of an IC device according to another embodiment;

FIG. 10 is a detailed view illustrating the gate structure of FIG. 9;

FIG. 11 is an enlarged view of a portion of EL2-2 of FIG. 10;

FIGS. 12 to 17 are cross-sectional views illustrating a method of manufacturing an IC device, according to an embodiment;

FIG. 18 is a cross-sectional view illustrating a method of manufacturing an IC device, according to an embodiment;

FIG. 19 is a cross-sectional view illustrating the method of manufacturing an integrated circuit according to an embodiment;

FIG. 20 is a system including an IC device according to aspects of the inventive concept; and

FIG. 21 is a memory card including a semiconductor device according to aspects of the inventive concept.

### DETAILED DESCRIPTION OF THE EMBODIMENTS

Hereinafter, the embodiments will be described in detail. The following embodiments may be implemented individually or by combining one or more thereof. Accordingly, aspects of the inventive concept are not interpreted to be limited to one embodiment.

In the present specification, the singular form of the components may include plurality of forms unless stated otherwise in context. In this specification, the drawings are depicted to explain aspects of the inventive concept more clearly.

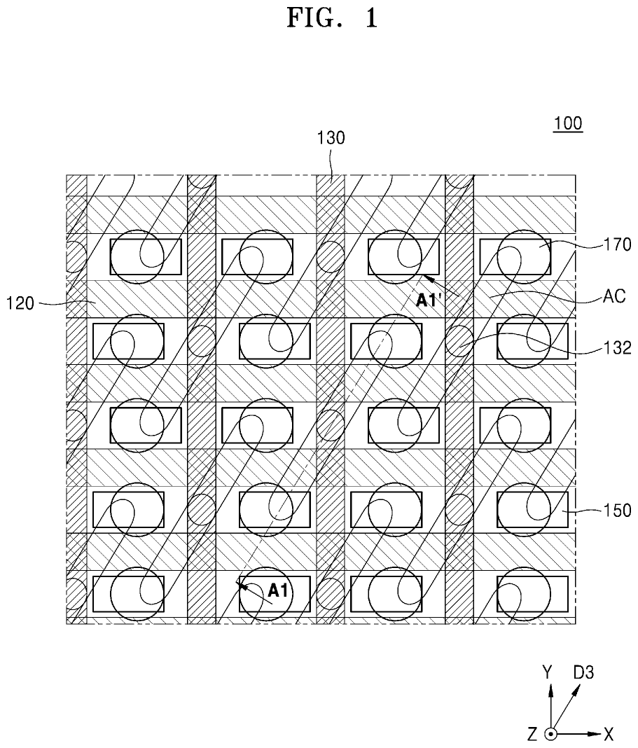

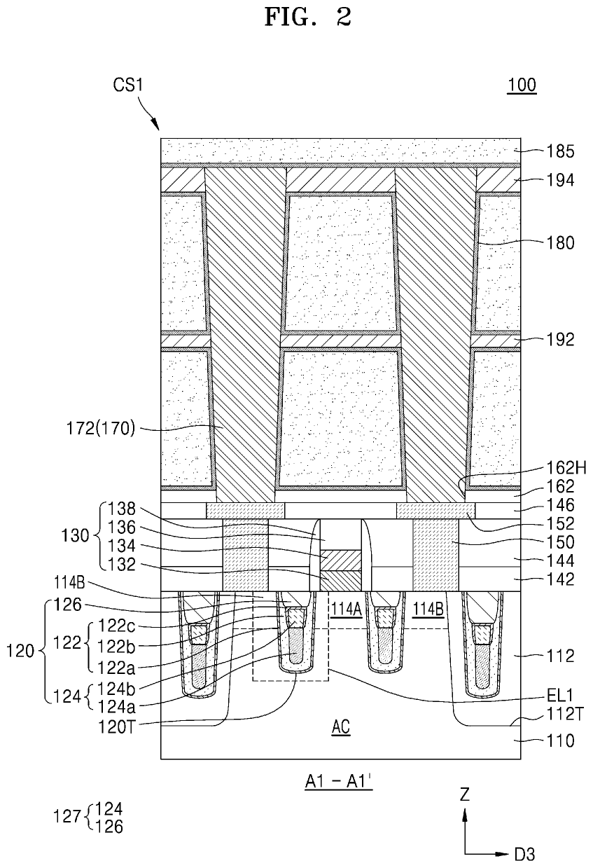

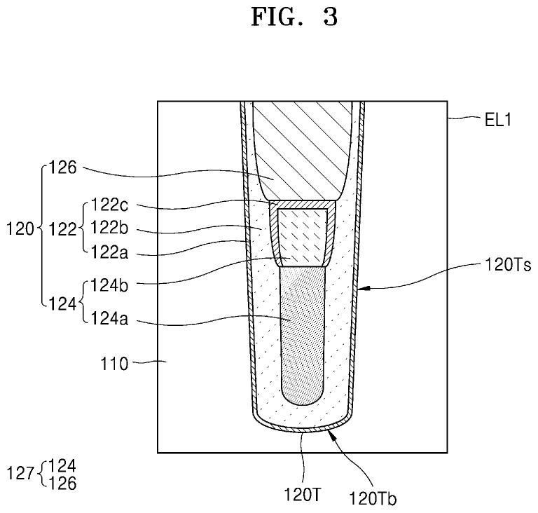

FIG. 1 is a layout view illustrating an integrated circuit (IC) device 100 according to an embodiment, FIG. 2 is a cross-sectional view taken along line A1-A1′ of FIG. 1, and FIG. 3 is an enlarged view of a portion EL1 of FIG. 2.

In detail, the layout view of the IC device 100 shown in FIG. 1 is provided as an example, and aspects of the inventive concept are not limited thereto. The IC device 100 may have an active region AC defined by a device isolation layer 112 on the substrate 110. The IC device 100 may be a dynamic random access memory device. In some embodiments, the substrate 110 may include or may be formed of semiconductor materials, such as Si, Ge, or SiGe, SiC, GaAs, InAs, or InP. In some embodiments, the substrate 110 may include a conductive region, e.g., a well doped with impurities or a structure doped with impurities.

The device isolation layer 112 may have a shallow trench isolation (STI) structure. For example, the device isolation layer 112 may include an insulating material filling a device isolation trench 112T formed in the substrate 110. The insulating material may include or may be formed of fluoride silicate glass (FSG), undoped silicate glass (USG), boro-phospho-silicate glass (BPSG), phospho-silicate glass (PSG), flowable oxide (FOX), plasma enhanced tetra-ethyl-ortho-silicate (PE-TEOS), or tonen silazene (TOSZ), but is not limited thereto.

As shown in FIG. 1, the active region AC may have a relatively long island shape having a minor axis and a major axis. The major axis of the active region AC may be arranged in a D3 direction parallel to an upper surface of the substrate 110. For example, the substrate 110 may extend in a first direction (X direction) and a second direction (Y direction), which is perpendicular to the first direction. The direction D3 may be oblique to the first direction and the second direction. In some embodiments, the active region AC may be doped with P-type or N-type impurities.

The substrate 110 may have a gate trench 120T extending in the X direction parallel to the upper surface of the substrate 110. The gate trench 120T may be referred to as a gate line trench. The gate trench 120T may intersect with the active region AC and may be formed at a predetermined depth (i.e., in a Z direction) from the upper surface of the substrate 110. The Z direction may be perpendicular to the X direction and the Y direction. A portion of the gate trench 120T may extend into the device isolation layer 112. The gate trench 120T may include a bottom portion 120Tb and the sidewall portion 120Ts.

A portion of the gate trench 120T formed in the device isolation layer 112 may include a bottom surface at a level lower (i.e., in the Z direction) than that of a portion of the gate trench 120T formed in the active region AC. In the following detailed description, the term “level” may refer to a vertical height in a direction perpendicular to the upper surface of the substrate 110, i.e., the Z direction.

A first source/drain region 114A and a second source/drain region 114B may be disposed in an upper portion of the active region AC on both sides of the gate trench 120T. The first source/drain region 114A and the second source/drain region 114B may be impurity regions doped with impurities having a conductivity type, different from that of impurities doped in the active region AC. N-type or P-type impurities may be doped in the first source/drain region 114A and the second source/drain region 114B.

The gate structure 120 may be formed inside the gate trench 120T. The gate structure 120 may include a gate electrode structure 127 and a gate insulating layer 122 formed on the gate electrode structure 127. The gate insulating layer 122 may have a thickness of a few angstroms Å to tens of angstroms Å. The gate electrode structure 127 may be formed to be apart from the bottom portion 120Tb and the sidewall portion 120Ts of the gate trench 120T.

The gate electrode structure 127 may include a gate electrode 124, which includes a first sub-gate electrode 124a formed in a lower portion of the gate trench 120T and a second sub-gate electrode 124b formed on the first sub-gate electrode 124a, and a gate capping layer 126 formed on the second sub-gate electrode 124b.

The first sub-gate electrode 124a may include a metal layer. In some embodiments, the first sub-gate electrode 124a may include or may be formed of at least one of W, WN, TiN, and TaN. The second sub-gate electrode 124b may be a material layer that adjusts a work function of the gate electrode structure 127. In some embodiments, the second sub-gate electrode 124b may include a polysilicon layer doped with impurities. The gate capping layer 126 may include a silicon nitride layer.

The gate insulating layer 122 may be formed between the gate trench 120T and the gate electrode structure 127. For example, the gate insulating layer 122 may be formed within the gate trench 120T such that gate insulating layer 122 is formed between surfaces/portions (e.g., the bottom portion 120Tb and the sidewall portion 120Ts) of the gate trench 120T. The gate insulating layer 122 may be in contact with the surfaces/portions of the gate trench 120T and the gate electrode 127. The gate insulating layer 122 may include a liner insulating layer 122a formed on the bottom portion 120Tb and the sidewall portion 120Ts of the gate trench 120T, a base insulating layer 122b formed between the liner insulating layer 122a on the bottom portion 120Tb and the sidewall portion 120Ts of the gate trench 120T and the gate electrode structure 127, and a reinforcing insulating layer 122c formed on a sidewall portion and an upper surface portion of the second sub-gate electrode 124b.

In some embodiments, the liner insulating layer 122a may include an insulating layer including silicon, such as a silicon oxide layer or a silicon nitride layer. In some embodiments, the liner insulating layer 122a may include the same material as that of the reinforcing insulating layer 122c to be described below. In some embodiments, the liner insulating layer 122a may not be formed. The base insulating layer 122b may include at least one selected from a silicon oxide layer, a silicon nitride layer, a silicon oxynitride layer, an oxide/nitride/oxide (ONO) layer, and a high-k material layer having a dielectric constant higher than that of the silicon oxide layer.

For example, the base insulating layer 122b may have a dielectric constant of about 10 to 25. In some embodiments, the base insulating layer 122b may include or may be formed of HfO₂, ZrO₂, Al₂O₃, HfAlO₃, Ta₂O₃, TiO₂, or combinations thereof, but is not limited thereto.

The reinforcing insulating layer 122c may be provided to improve the reliability of the gate insulating layer 122 by reinforcing a thickness of the gate insulating layer 122 on a sidewall of the second sub-gate electrode 124b. The reinforcing insulating layer 122c may be formed at a field concentration region of the gate insulating layer 122 at the sidewall portion or the corner portion of the second sub-gate electrode 124b when the IC device 100 operates. In some embodiments, the reinforcing insulating layer 122c may include an insulating layer including silicon. The reinforcing insulating layer 122c may include SiO₂, Si₃N₄, SiOC, SiON, SiCN, or SiOCN.

As described above, the IC device 100 according to aspects of the inventive concept may include the gate trench 120T, the gate electrode structure 127, and the gate insulating layer 122 including the liner insulating layer 122a, the base insulating layer 122b and the reinforcing insulating layer 122c. The components of the IC device 100 may be applied to any device even if the device is not a DRAM device.

On the first source/drain region 114A, a bit line structure 130 may be formed to be parallel to the upper surface of the substrate 110 and extending in the Y direction. The bit line structure 130 may include a bit line contact 132, a bit line 134, a bit line capping layer 136, and a bit line spacer 138 sequentially stacked on the substrate 110.

For example, the bit line contact 132 may include a polysilicon layer, and the bit line 134 may include a metal layer. The bit line capping layer 136 may include an insulating layer, such as a silicon nitride layer or a silicon oxygen layer. The bit line spacer 138 may have a single layer structure or multi-layer structure including an insulating layer, such as a silicon oxide layer, a silicon oxynitride layer, or a silicon nitride layer.

A first insulating layer 142 and a second insulating layer 144 may be sequentially disposed on the substrate 110. The bit line structure 130 may be connected to the first source/drain region 114A through the first insulating layer 142 and the second insulating layer 144.

A capacitor contact 150 may be disposed on the second source/drain region 114B. A sidewall of the capacitor contact 150 may be surrounded by the first and second insulating layers 142 and 144. In some embodiments, the capacitor contact 150 may include a polysilicon layer and a metal layer doped with impurities. A third insulating layer 146 may be disposed on the second insulating layer 144.

A landing pad 152 may be disposed to be connected to the capacitor contact 150 through the third insulating layer 146. As shown in FIG. 2, the landing pad 152 vertically and entirely overlaps the capacitor contact 150 and may have a width greater than that of the capacitor contact 150. In some embodiments, the landing pad 152 may include at least one of a metal, such as ruthenium (Ru), titanium (Ti), tantalum (Ta), niobium (Nb), iridium (Ir), molybdenum (Mo), tungsten (W), etc. and a conductive metal nitride, such as titanium nitride (TiN), tantalum nitride (TaN), niobium nitride (NbN), molybdenum nitride (MoN), tungsten nitride (WN), etc. In some embodiments, the landing pad 152 may include a titanium nitride (TiN).

An etch stop layer 162 may be formed on the landing pad 152 and the third insulating layer 146. The etch stop layer 162 may have an opening 162H exposing an upper surface of the landing pad 152. A capacitor structure CS1 may be disposed on the etch stop layer 162 and the third insulating layer 146.

The capacitor structure CS1 may include a lower electrode 170 electrically connected to the capacitor contact 150 with the landing pad 152 therebetween, a dielectric layer 180 covering the lower electrode 170, and an upper electrode 185 on the dielectric layer 180.

The lower electrode 170 may be disposed on the landing pad 152, and a bottom portion of the lower electrode 170 may be located in the opening portion 162H of the etch stop layer 162. A width of the bottom portion of the lower electrode 170 may be less than a width of the landing pad 152, and accordingly, the entire bottom surface of the lower electrode 170 may contact the landing pad 152. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

As shown in FIG. 2, the lower electrode 170 may have a pillar or columnar shape extending in the third direction (i.e., Z direction). The lower electrode 170 may have a circular horizontal cross-section, but aspects of the inventive concept are not limited thereto. In other embodiments, the horizontal cross-section of the lower electrode 170 may be various polygons and various rounded polygons, such as an ellipse, a quadrangle, a rounded quadrangle, a rhombus, and a trapezoid.

As shown in FIG. 1, the lower electrode 170 and the capacitor contact 150 may be repeatedly arranged in the first direction (the X direction) and the second direction (the Y direction). The lower electrode 170 may include at least one selected from a metal, such as ruthenium (Ru), titanium (Ti), tantalum (Ta), niobium (Nb), iridium (Ir), molybdenum (Mo), and tungsten (W), a conductive metal nitride, such as titanium nitride (TiN), tantalum nitride (TaN), niobium nitride (NbN), molybdenum nitride (MoN), and tungsten nitride (WN), and a conductive metal oxide, such as iridium oxide (IrO₂), ruthenium oxide (RuO₂), and strontium ruthenium oxide (SrRuO₃).

A first supporter 192 and a second supporter 194 may be located on a sidewall of the lower electrode 170 and apart from each other. The first supporter 192 and the second supporter 194 may be located between the lower electrode 170 and another lower electrode 170 adjacent thereto. The first supporter 192 and the second supporter 194 may function as support members to prevent the lower electrode 170 from falling or collapsing. The first supporter 192 and the second supporter 194 may include or may be formed of silicon nitride, silicon oxynitride, silicon boron nitride (SiBN), or silicon carbon nitride (SiCN).

The dielectric layer 180 may be disposed on a sidewall and an upper surface of the lower electrode 170. The dielectric layer 180 may include at least one of zirconium oxide, hafnium oxide, titanium oxide, niobium oxide, tantalum oxide, yttrium oxide, strontium titanium oxide, barium strontium titanium oxide, scandium oxide, and lanthanide oxide.

The upper electrode 185 covering the lower electrode 170 may be disposed on the dielectric layer 180. The upper electrode 185 may be formed using a forming material of the lower electrode 170.

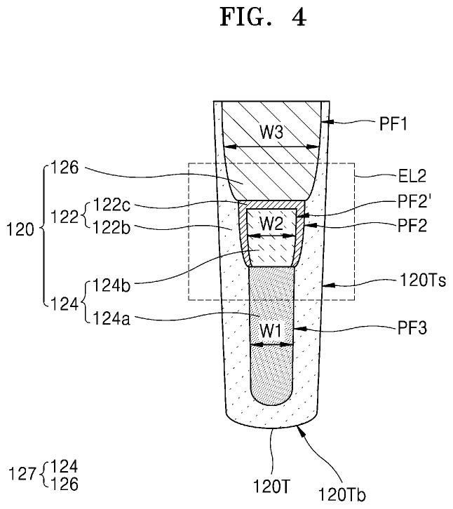

FIG. 4 is a detailed view illustrating the gate structure 120 of FIGS. 1 to 3, and FIG. 5 is an enlarged view of a portion of EL2 of FIG. 4.

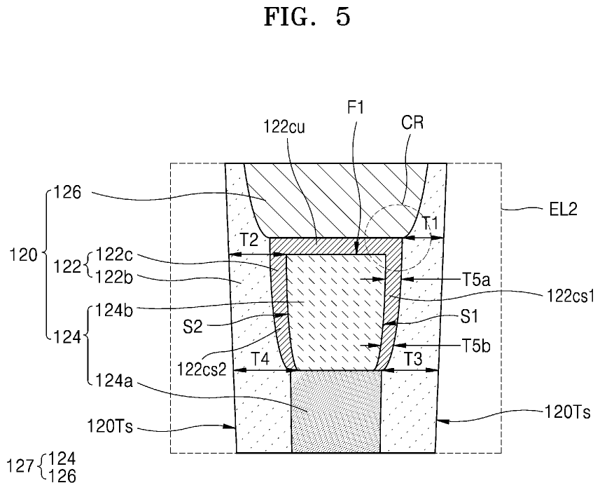

In detail, in FIGS. 4 and 5, the descriptions given above with respect to FIGS. 1 to 3 are briefly described or omitted. As described above, the gate structure 120 may include the gate electrode structure 127. The gate electrode structure 127 may be formed to be apart from the bottom portion 120Tb and the sidewall portion 120Ts of the gate trench 120T.

The gate electrode structure 127 may include the gate electrode 124, which includes the first sub-gate electrode 124a formed in a lower level of the gate trench 120T and the second sub-gate electrode 124b formed on the first sub-gate electrode 124a, and a gate capping layer 126 formed on the second sub-gate electrode 124b.

As shown in FIG. 4, a third width W3 at a middle level of the gate capping layer 126 may be greater than a second width W2 at a middle level of the second sub-gate electrode 124b. The second width W2 at the middle level of the second sub-gate electrode 124b may be greater than a first width W1 at the middle level of the first sub-gate electrode 124a.

As shown in FIG. 4, a first sidewall profile PF1 of the gate capping layer 126 may be curved so that a width of the gate capping layer 126 gradually decreases along the third direction (i.e., Z direction) from an upper surface portion of the gate capping layer 126 to a lower surface portion thereof. A second sidewall profile PF2′ of the second sub-gate electrode 124b may be curved so that a width of the second sub-gate electrode 124b gradually decreases along the third direction from an upper surface portion of the second sub-gate electrode 124b to a lower surface portion thereof.

A third sidewall profile PF3 of the first sub-gate electrode 124a may be configured so that a width of the first sub-gate electrode 124a along the third direction from an upper surface portion of the first sub-gate electrode 124a to a lower surface portion thereof is substantially uniform. Terms such as “same,” “equal,” “planar,” “coplanar,” or “uniform,” as used herein encompass identicality or near identicality including variations that may occur, for example, due to manufacturing processes. The term “substantially” may be used herein to emphasize this meaning, unless the context or other statements indicate otherwise.

As described above, the gate structure 120 may include the gate insulating layer 122. The gate insulating layer 122 may include the base insulating layer 122b formed between the bottom portion 120Tb and the sidewall portion 120Ts of the gate trench 120T and the gate electrode structure 127 and the reinforcing insulating layer 122c formed on the sidewall portion and the upper surface portion of the second sub-gate electrode 124b. In FIGS. 4 and 5, for convenience, the liner insulating layer 122a constituting a part of the gate insulating layer 122 is not shown.

As shown in FIG. 5, the reinforcing insulating layer 122c may include sidewall reinforcing insulating layers 122cs1 and 122cs2 respectively formed on sidewall portions S1 and S2 of the second sub-gate electrode 124b and an upper surface reinforcing insulating layer 122cu formed on an upper surface portion F1 of the second sub-gate electrode 124b. The reinforcing insulating layer 122c may reinforce a corner portion CR of the second sub-gate electrode 124b.

As shown in FIG. 4, an expanded second sidewall profile PF2 of sidewall reinforcing insulating layers 122cs1 and 122cs2 formed on the sidewall of the second sub-gate electrode 124b may be curved so that the width of the second sub-gate electrode 124b gradually decreases along the third direction from an upper surface portion of the second sub-gate electrode 124b to a lower surface portion thereof.

As shown in FIGS. 4 and 5, a second thickness T2 of the gate insulating layer 122, i.e., the base insulating layer 122b and the reinforcing insulating layer 122c, between the second sub-gate electrode 124b and the gate trench 120T (i.e., the sidewall portion 120Ts of the gate trench 120T) on the top level of the second sub-gate electrode 124b may be greater than a first thickness T1 of the gate insulating layer 122, i.e., the base insulating layer 122b, between the gate capping layer 126 and the gate trench 120T (i.e., the sidewall portion 120Ts of the gate trench 120T) on the bottom level of the gate capping layer 126.

For example, the second thickness T2 of the gate insulating layer 122, i.e., the base insulating layer 122b and the reinforcing insulating layer 122c, between the sidewall portion of the second sub-gate electrode 124b and the sidewall portion 120Ts of the gate trench 120T on the top level of the second sub-gate electrode 124b may be greater than the first thickness T1 of the gate insulating layer 122, i.e., the base insulating layer 122b, between the sidewall portion of the gate capping layer 126 and the sidewall portion 120Ts of the gate trench 120T on the bottom level of the gate capping layer 126.

As shown in FIGS. 4 and 5, a fourth thickness T4 of the gate insulating layer 122, i.e., the base insulating layer 122b and the reinforcing insulating layer 122c, between the second sub-gate electrode 124b and the gate trench 120T (i.e., the sidewall portion 120Ts of the gate trench 120T) on the bottom level of the second sub-gate electrode 124b may be greater than a third thickness T3 of the gate insulating layer 122, i.e., the base insulating layer 122b, between the first sub-gate electrode 124a and the gate trench 120T (i.e., the sidewall portion 120Ts of the gate trench 120T) on the top level of the first sub-gate electrode 124a.

For example, the fourth thickness T4 of the gate insulating layer 122, i.e., the base insulating layer 122b and the reinforcing insulating layer 122c, between the sidewall portion of the second sub-gate electrode 124b and the sidewall portion 120Ts of the gate trench 120T on the bottom level of the second sub-gate electrode 124b may be greater than the third thickness T3 of the gate insulating layer 122, i.e., the base insulating layer 122b, between the side wall portion of the first sub-gate electrode 124a and the sidewall portion 120Ts of the gate trench 120T on the top level of the first sub-gate electrode 124a.

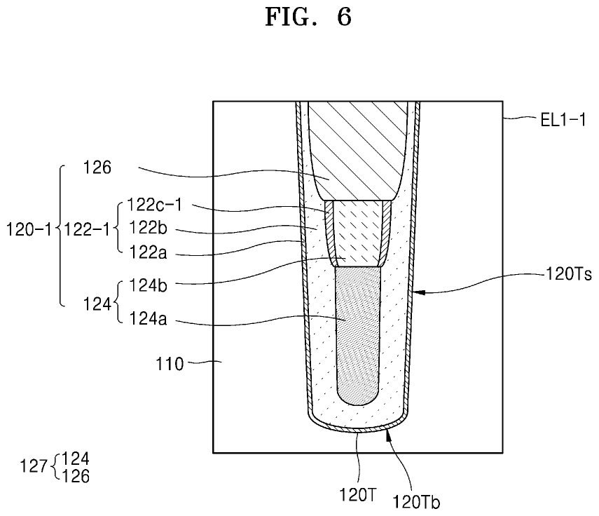

FIG. 6 is an enlarged view of a gate structure 120-1 of an IC device according to another embodiment.

Specifically, the gate structure 120-1 shown in FIG. 6 may be another embodiment of the gate structure 120 of FIG. 3. A portion EL1-1 shown in FIG. 6 may be another embodiment of the enlarged view of the portion EL1 of FIG. 2. In FIG. 6, the same descriptions as those of FIG. 3 are briefly given or omitted.

The gate structure 120-1 may be the same as the gate structure 120 of FIG. 3, except that a reinforcing insulating layer 122c-1 is not formed on an upper surface portion of the second sub-gate electrode 124b. The gate structure 120-1 may be formed inside of the gate trench 120T.

The gate structure 120-1 may include a gate electrode structure 127 and a gate insulating layer 122-1. The gate electrode structure 127 may be formed to be apart from the bottom portion 120Tb and the sidewall portion 120Ts of the gate trench 120T. The gate electrode structure 127 may include the gate electrode 124 and the gate capping layer 126, and the gate electrodes may include the first sub-gate electrode 124a and the second sub-gate electrode 124b.

The gate insulating layer 122-1 may be formed between the gate trench 120T (i.e., the sidewall portion 120Ts of the gate trench 120T) and the gate electrode structure 127. The gate insulating layer 122-1 may include a liner insulating layer 122a formed on the bottom portion 120Tb and the sidewall portion 120Ts of the gate trench 120T, a base insulating layer 122b formed between the liner insulating layer 122a on the bottom portion 120Tb and the sidewall portion 120Ts of the gate trench 120T and the gate electrode structure 127, and a reinforcing insulating layer 122c-1 formed on the sidewall portion of the second sub-gate electrode 124b. The liner insulating layer 122a and the base insulating layer 122b are described above, so descriptions thereof are omitted here.

The reinforcing insulating layer 122c-1 may be provided to improve the reliability of the gate insulating layer 122-1 by reinforcing the thickness of the gate insulating layer 122-1 on the sidewall of the second sub-gate electrode 124b. The reinforcing insulating layer 122c-1 may be formed at the field concentration region of the gate insulating layer 122-1 of the sidewall portion of the second sub-gate electrode 124b when the IC device (100 of FIGS. 1 and 2) operates. In some embodiments, the reinforcing insulating layer 122c-1 may include an insulating layer including silicon. The reinforcing insulating layer 122c-1 may include or may be formed of SiO₂, Si₃N₄, SiOC, SiON, SiCN, or SiOCN.

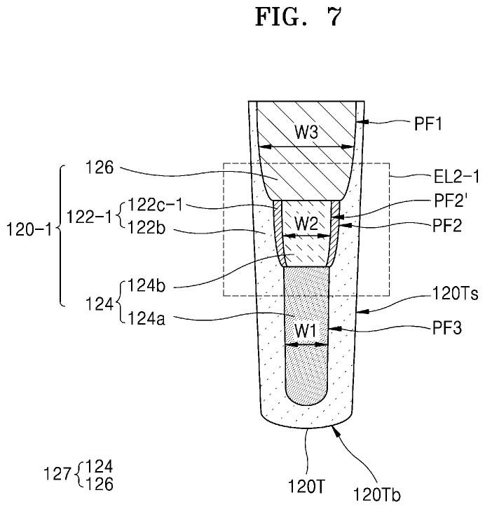

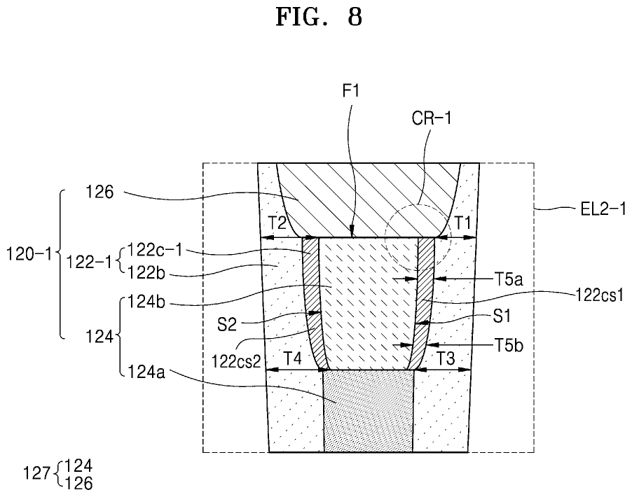

FIG. 7 is a detailed view illustrating the gate structure 120-1 of FIG. 6, and FIG. 8 is an enlarged view of a portion EL2-1 of FIG. 7.

Specifically, in FIGS. 7 and 8, the description given above with respect to FIG. 6 is briefly given or omitted. As described above, the gate structure 120-1 may include the gate electrode structure 127.

The gate electrode structure 127 may include the gate electrode 124, which includes the first sub-gate electrode 124a and the second sub-gate electrode 124b, and the gate capping layer 126. As shown in FIG. 7, the third width W3 at the middle level of the gate capping layer 126 may be greater than the second width W2 at the middle level of the second sub-gate electrode 124b. The second width W2 at the middle level of the second sub-gate electrode 124b may be greater than the first width W1 at the middle level of the first sub-gate electrode 124a.

As shown in FIG. 7, the first sidewall profile PF1 of the gate capping layer 126 may be curved so that the width of the gate capping layer 126 gradually decreases along the third direction from the upper surface portion of the gate capping layer 126 to the lower surface portion thereof. A second sidewall profile PF2′ of the second sub-gate electrode 124b may be curved so that the width of the second sub-gate electrode 124b gradually decreases along the third direction from the upper surface portion of the second sub-gate electrode 124b to the lower surface portion thereof.

The third sidewall profile PF3 of the first sub-gate electrode 124a may be configured so that the width of the first sub-gate electrode 124a is substantially uniform along the third direction from the upper surface portion of the first sub-gate electrode 124a to the lower surface portion thereof.

As described above, the gate structure 120-1 may include a gate insulating layer 122-1. The gate insulating layer 122-1 may include a base insulating layer 122b formed between the bottom portion 120Tb and the sidewall portion 120Ts of the gate trench 120T and the gate electrode structure 127 and a reinforcing insulating layer 122c-1 formed on the sidewall portion of the second sub-gate electrode 124b. In FIGS. 7 and 8, for convenience, the liner insulating layer 122a constituting the gate insulating layer 122-1 is not shown.

As shown in FIG. 8, the reinforcing insulating layer 122c-1 may include sidewall reinforcing insulating layers 122cs1 and 122cs2 respectively formed on the sidewalls S1 and S2 of the second sub-gate electrode 124b. The reinforcing insulating layer 122c-1 may not be formed on the upper surface portion F1 of the second sub-gate electrode 124b. The reinforcing insulating layer 122c-1 may reinforce a corner portion CR-1 of the second sub-gate electrode 124b.

As shown in FIG. 7, the expanded second sidewall profile PF2 of the sidewall reinforcing insulating layers 122cs1 and 122cs2 formed on the sidewall of the second sub-gate electrode 124b is curved so that the width of the second sub-gate electrode 124b gradually decreases along the third direction from the upper surface portion of the second sub-gate electrode 124b to the lower surface portion thereof.

As shown in FIG. 8, the second thickness T2 of the gate insulating layer 122-1, i.e., the base insulating layer 122b and the reinforcing insulating layer 122c-1, between the second sub-gate electrode 124b and the gate trench 120T (i.e., the sidewall portion 120Ts of the gate trench 120T) on the top level of the second sub-gate electrode 124b may be greater than the first thickness T1 of the gate insulating layer 122-1, i.e., the base insulating layer 122b, between the gate capping layer 126 and the gate trench 120T (i.e., the sidewall portion 120Ts of the gate trench 120T) on the bottom level of the gate capping layer 126.

For example, the second thickness T2 of the gate insulating layer 122-1, i.e., the base insulating layer 122b and the reinforcing insulating layer 122c-1, between the sidewall portion of the second sub-gate electrode 124b and the sidewall portion 120Ts of the gate trench 120T on the top level of the second sub-gate electrode 124b may be greater than the first thickness T1 of the gate insulating layer 122-1, i.e., the base insulating layer 122b, between the sidewall portion of the gate capping layer 126 and the sidewall portion 120Ts of the gate trench 120T on the bottom level of the gate capping layer 126.

As shown in FIG. 8, a fourth thickness T4 of the gate insulating layer 122-1, i.e., the base insulating layer 122b and the reinforcing insulating layer 122c-1, between the second sub-gate electrode 124b and the gate trench 120T (i.e., the sidewall portion 120Ts of the gate trench 120T) on the bottom level of the second sub-gate electrode 124b may be greater than a third thickness T3 of the gate insulating layer 122-1, i.e., the base insulating layer 122b, between the first sub-gate electrode 124a and the gate trench 120T (i.e., the sidewall portion 120Ts of the gate trench 120T) on the top level of the first sub-gate electrode 124a.

For example, the fourth thickness T4 of the gate insulating layer 122-1, i.e., the base insulating layer 122b and the reinforcing insulating layer 122c-1, between the sidewall portion of the second sub-gate electrode 124b and the sidewall portion 120Ts of the gate trench 120T on the bottom level of the second sub-gate electrode 124b may be greater than the third thickness T3 of the gate insulating layer 122-1, i.e., the base insulating layer 122b, between the sidewall portion of the first sub-gate electrode 124a and the sidewall portion 120Ts of the gate trench 120T on the top level of the first sub-gate electrode 124a.

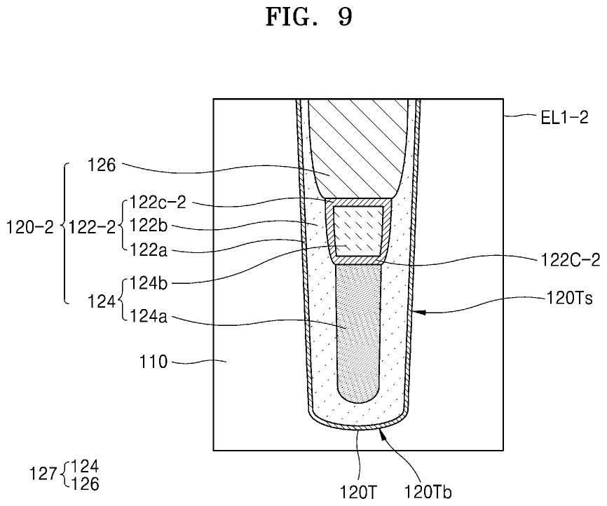

FIG. 9 is an enlarged view of a gate structure 120-2 of an IC device according to another embodiment.

Specifically, the gate structure 120-2 shown in FIG. 9 may be another embodiment of the gate structure 120 of FIG. 3. A portion EL1-2 shown in FIG. 9 may be another embodiment of the enlarged view of the portion EL1 of FIG. 2. In FIG. 9, the same descriptions as those of FIG. 3 are briefly given or omitted.

The gate structure 120-2 may be the same as the gate structure 120 of FIG. 3, except that a reinforcing insulating layer 122c-2 is further formed on a lower surface portion of the second sub-gate electrode 124b. The gate structure 120-2 may include a gate electrode structure 127 and a gate insulating layer 122-2.

The gate electrode structure 127 may be formed to be apart from the bottom portion 120Tb and the sidewall portion 120Ts of the gate trench 120T. The gate electrode structure 127 may include the gate electrode 124 and the gate capping layer 126, and the gate electrodes 124 may include the first sub-gate electrode 124a and the second sub-gate electrode 124b.

The first sub-gate electrode 124a may include a metal layer. The second sub-gate electrode 124b may be a material layer that adjusts a work function of the gate electrode structure 127. The second sub-gate electrode 124b may include a polysilicon layer doped with impurities. The gate capping layer 126 may include a silicon nitride layer.

The gate insulating layer 122-2 may be formed between the gate trench 120T (i.e., the sidewall portion 120Ts of the gate trench 120T) and the gate electrode structure 127. The gate insulating layer 122-2 may include a liner insulating layer 122a formed on the bottom portion 120Tb and sidewall portion 120Ts of the gate trench 120T, a base insulating layer 122b formed between the liner insulating layer 122a on the bottom portion 120Tb and the sidewall portion 120Ts of the gate trench 120T and the gate electrode structure 127, and a reinforcing insulating layer 122c-2 formed on the sidewall portion, the upper surface portion, and the bottom portion of the second sub-gate electrode 124b. The liner insulating layer 122a and the base insulating layer 122b are described above, and thus, descriptions thereof are omitted here.

The reinforcing insulating layer 122c-2 may be provided to improve the reliability of the gate insulating layer 122-2 by reinforcing the thickness of the gate insulating layer 122-2 at the sidewall portion and a corner portion of the second sub-gate electrode 124b. The reinforcing insulating layer 122c-2 may be formed at the field concentration region of the gate insulating layer 122 at the sidewall portion and the corner portion of the second sub-gate electrode 124b when the IC device 100 operates. In some embodiments, the reinforcing insulating layer 122c-2 may be an insulating layer including silicon. The reinforcing insulating layer 122c-2 may include or may be formed of SiO₂, Si₃N₄, SiOC, SiON, SiCN, or SiOCN.

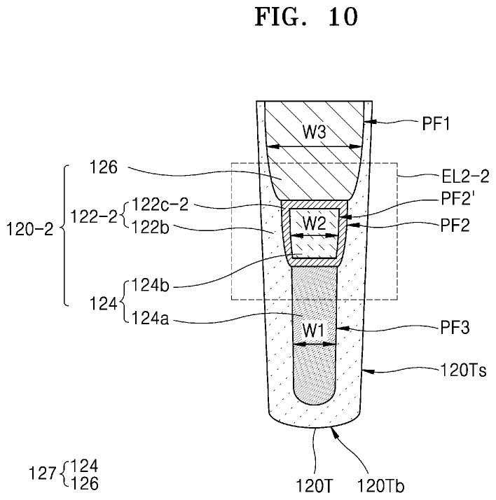

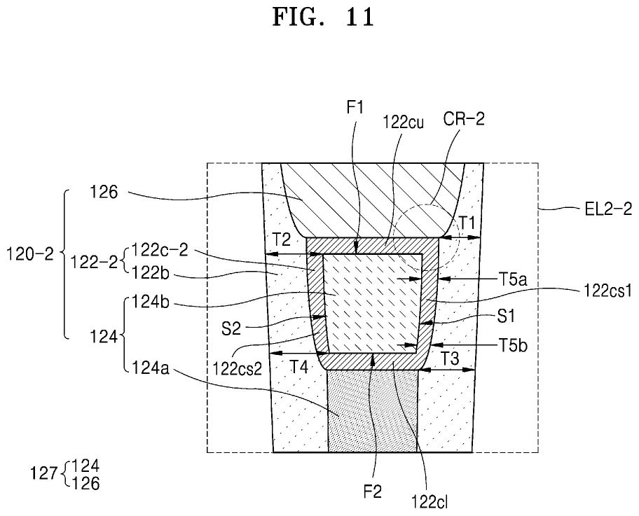

FIG. 10 is a detailed view illustrating the gate structure of FIG. 9, and FIG. 11 is an enlarged view of the portion EL2-2 of FIG. 10.

In detail, in FIGS. 10 and 11, the descriptions given above with respect to FIG. 9 are briefly given or omitted. As described above, the gate structure 120-2 may include the gate electrode structure 127. The gate electrode structure 127 may be formed apart from the bottom portion 120Tb and the sidewall portion 120Ts of the gate trench 120T.

The gate electrode structure 127 may include the gate electrode 124 and the gate capping layer 126, and the gate electrode 124 may include the first sub-gate electrode 124a and the second sub-gate electrode 124b. As shown in FIG. 10, the third width W3 at the middle level of the gate capping layer 126 may be greater than the second width W2 at the middle level of the second sub-gate electrode 124b. The second width W2 at the middle level of the second sub-gate electrode 124b may be greater than the first width W1 at the middle level of the first sub-gate electrode 124a.

As shown in FIG. 10, the first sidewall profile PF1 of the gate capping layer 126 may be curved so that the width of the gate capping layer 126 gradually decreases along the third direction from the upper surface portion of the gate capping layer 126 to the lower surface portion thereof. The second sidewall profile PF2′ of the second sub-gate electrode 124b may be curved so that the width of the second sub-gate electrode 124b gradually decreases along the third direction from the upper surface portion of the second sub-gate electrode 124b to the lower surface portion thereof.

The third sidewall profile PF3 of the first sub-gate electrode 124a may be configured so that the width of the first sub-gate electrode 124a is substantially uniform along the third direction from the upper surface portion of the first sub-gate electrode 124a to the lower surface portion thereof.

As described above, the gate structure 120-2 may include a gate insulating layer 122-2. The gate insulating layer 122-2 may include the base insulating layer 122b formed between the bottom portion 120Tb and the sidewall portion 120Ts of the gate trench 120T and the gate electrode structure 127 and a reinforcing insulating layer 122c-2 formed on the sidewall portion, the upper surface portion, and the lower surface portion of the second sub-gate electrode 124b. In FIGS. 10 and 11, for convenience, the liner insulating layer 122a constituting the gate insulating layer 122-2 is not shown.

As shown in FIG. 11, the reinforcing insulating layer 122c-2 may include sidewall reinforcing insulating layers 122cs1 and 122cs2 respectively formed on of the sidewall portions S1 and S2 of the second sub-gate electrode 124b, an upper surface reinforcing insulating layer 122cu, and a lower surface reinforcing insulating layer 122cl respectively formed on the upper surface portion F1, and the lower surface portion F2 of the second sub-gate electrode 124b. The reinforcing insulating layer 122c-2 may reinforce the corner portion CR-2 of the second sub-gate electrode 124b.

As shown in FIG. 10, the expanded second sidewall profile PF2 of the sidewall reinforcing insulating layers 122cs1 and 122cs2 formed on the sidewall of the second sub-gate electrode 124b are curved so that the width of the second sub-gate electrode 124b gradually decreases in a direction from the upper surface portion of the second sub-gate electrode 124b to the lower surface portion thereof.

As shown in FIG. 11, the second thickness T2 of the gate insulating layer 122-2, i.e., the base insulating layer 122b and the reinforcing insulating layer 122c-2, between the second sub-gate electrode 124b and the gate trench 120T (i.e., the sidewall portion 120Ts of the gate trench 120T) on the top level of the second sub-gate electrode 124b may be greater than the first thickness T1 of the gate insulating layer 122-2, i.e., the base insulating layer 122b, between the gate capping layer 126 and the gate trench 120T (i.e., the sidewall portion 120Ts of the gate trench 120T) on the bottom level of the gate capping layer 126.

For example, the second thickness T2 of the gate insulating layer 122-2, i.e., the base insulating layer 122b and the reinforcing insulating layer 122c-2, between the sidewall portion of the second sub-gate electrode 124b and the sidewall portion 120Ts of the gate trench 120T on the top level of the second sub-gate electrode 124b may be greater than the first thickness T1 of the gate insulating layer 122-2, i.e., the base insulating layer 122b, between the sidewall portion of the gate capping layer 126 and the sidewall portion 120Ts of the gate trench 120T on the bottom level of the gate capping layer 126.

As shown in FIG. 11, the fourth thickness T4 of the gate insulating layer 122-2, i.e., the base insulating layer 122b and the reinforcing insulating layer 122c-2, between the second sub-gate electrode 124b and the gate trench 120T (i.e., the sidewall portion 120Ts of the gate trench 120T) on the bottom level of the second sub-gate electrode 124b may be greater than a third thickness T3 of the gate insulating layer 122-2, i.e., the base insulating layer 122b, between the first sub-gate electrode 124a and the gate trench 120T (i.e., the sidewall portion 120Ts of the gate trench 120T) on the top level of the first sub-gate electrode 124a.

For example, the fourth thickness T4 of the gate insulating layer 122-2, i.e., the base insulating layer 122b and the reinforcing insulating layer 122c-2, between the sidewall portion of the second sub-gate electrode 124b and the sidewall portion 120Ts of the gate trench 120T on the bottom level of the second sub-gate electrode 124b may be greater than the third thickness T3 of the gate insulating layer 122-2, i.e., the base insulating layer 122b, between the sidewall portion of the first sub-gate electrode 124a and the sidewall portion 120Ts of the gate trench 120T on the top level of the first sub-gate electrode 124a.

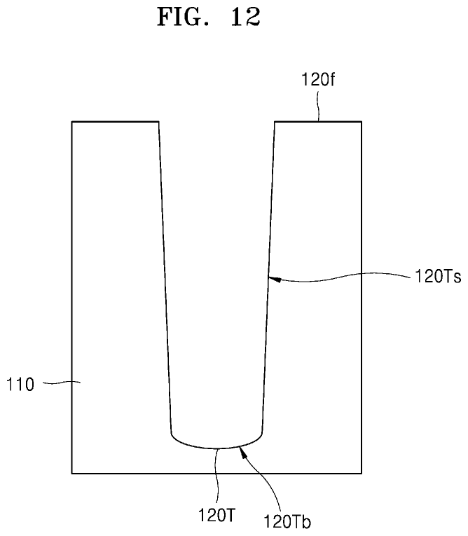

FIGS. 12 to 17 are cross-sectional views illustrating a method of manufacturing an IC device, according to an embodiment.

In detail, FIGS. 12 to 17 may illustrate a method of manufacturing the IC device 100 shown in FIGS. 1 to 5. FIGS. 12 to 17 may be cross-sectional views of a manufacturing method of FIGS. 3 to 5. In FIGS. 12 to 17, the descriptions given above with respect to FIGS. 1 to 5 are briefly given or omitted.

Referring to FIG. 12, the gate trench 120T is formed in the substrate 110. The gate trench 120T may be formed by forming a mask pattern (not shown) on the substrate 110, and etching the substrate 110 by using the mask pattern as an etch mask.

The gate trench 120T may be formed to have a predetermined depth from a surface 120f of the substrate 110. The gate trench 120T may include the bottom portion 120Tb and the sidewall portion 120Ts.

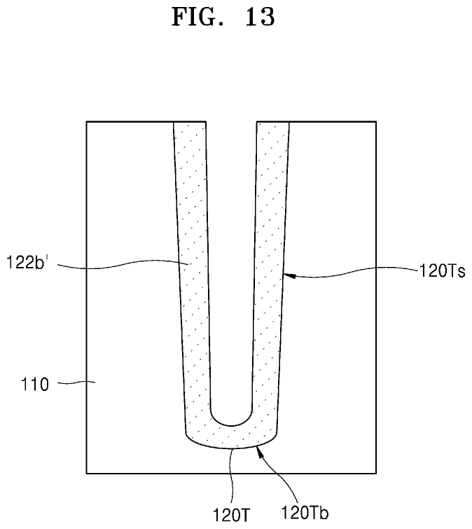

Referring to FIG. 13, a base insulating material layer 122b′ is formed on the bottom portion 120Tb and the sidewall portion 120Ts of the gate trench 120T. The base insulating material layer 122b′ may be a base insulating layer (122b of FIG. 3) formed through a post process. The base insulating material layer 122b′ may be formed of the same material as the base insulating layer (122b of FIG. 3) as described above.

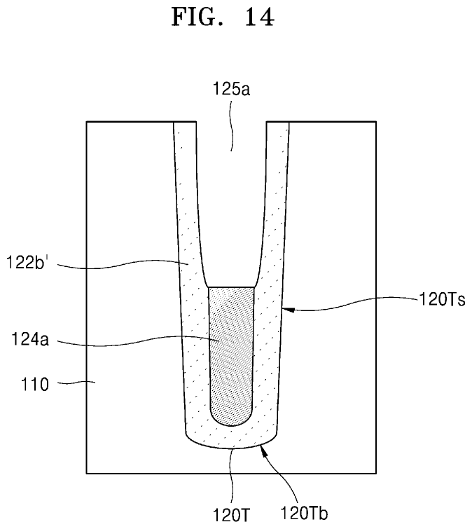

Referring to FIG. 14, a first sub-gate electrode 124a is formed on the base insulating material layer 122b′ inside the gate trench 120T. After forming a metal layer filling the inside of the gate trench 120T on the base insulating material layer 122b′, the upper side of the metal layer is removed by a certain height through an etch back process to form the first sub-gate electrode 124a. A first inner hole 125a may be formed inside the gate trench 120T on top of the first sub-gate electrode 124a.

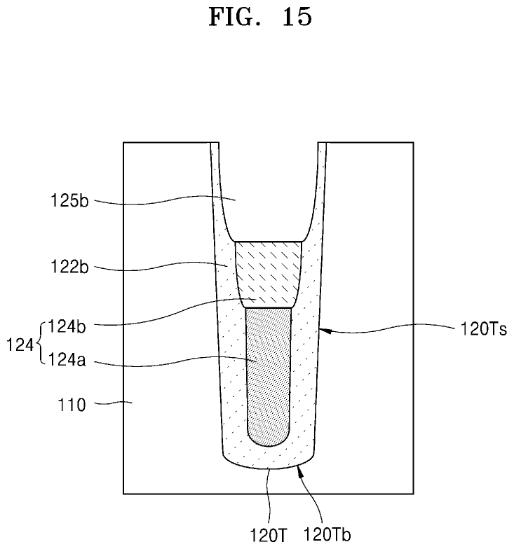

Referring to FIG. 15, a second sub-gate electrode 124b is formed on the base insulating material layer (122b′ in FIG. 14) and the first sub-gate electrode 124a inside the gate trench 120T. After forming a polysilicon layer doped with impurities that fill the first inner hole 125a on the base insulating material layer (122b′ in FIG. 14) and the first sub-gate electrode 124a inside the gate trench 120T, an upper portion of the polysilicon layer doped with impurities is removed by a certain height through an etch back process to form the second sub-gate electrode 124b. A second inner hole 125b may be formed inside the gate trench 120T on top of the second sub-gate electrode 124b.

Through this process, the base insulating material layer (122b′ in FIG. 14) may be formed as a base insulating layer 122b. A gate electrode 124 including the first sub-gate electrode 124a and the second sub-gate electrode 124b formed on the first sub-gate electrode 124a may be formed.

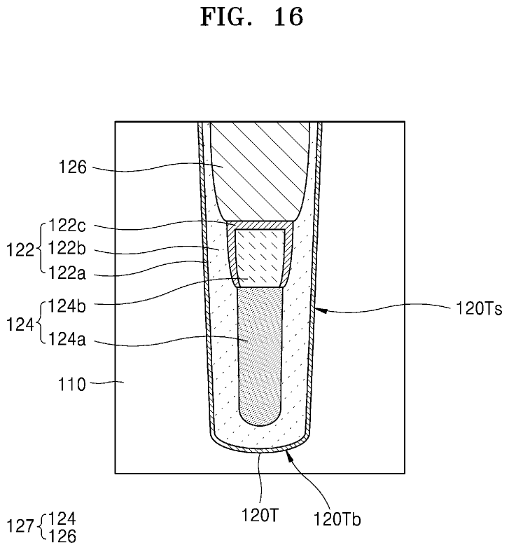

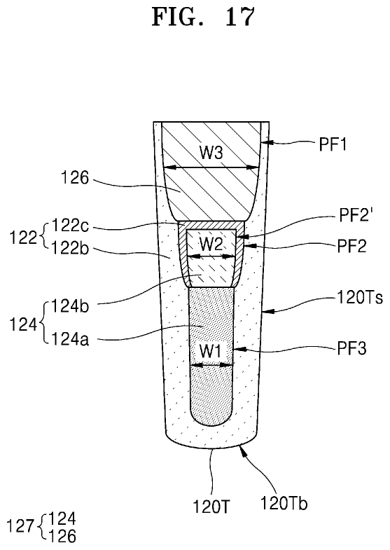

Referring to FIGS. 16 and 17, as shown in FIG. 16, the liner insulating layer 122a is formed on the bottom portion 120Tb and the sidewall portion 120Ts of the gate trench 120T and the reinforcing insulating layer 122c is formed on the sidewall portion and the upper surface portion of the second sub-gate electrode 124b. The liner insulating layer 122a may be formed simultaneously with the reinforcing insulating layer 122c.

The liner insulating layer 122a and the reinforcing insulating layer 122c may be formed by oxidizing or nitrating the bottom portion 120Tb and the sidewall portion 120Ts of the gate trench 120T and the sidewall portion and the upper surface portion of the second sub-gate electrode 124b. Through this process, the gate insulating layer 122 including the liner insulating layer 122a, the base insulating layer 122b, and the reinforcing insulating layer 122c may be formed.

Subsequently, the gate capping layer 126 filling the second inner hole (125b of FIG. 15) on the second sub-gate electrode 124b is formed. The gate capping layer 126 may be formed by filling the second inner hole (125b of FIG. 15) on the second sub-gate electrode 124b with an insulating layer and then planarizing the insulating layer so that the upper surface of the substrate 110 is exposed. Through this process, the gate electrode structure 127 including the gate electrode 124 and the gate capping layer 126 may be formed.

Here, the widths W1, W2, and W3 of the first sub-gate electrode 124a, the second sub-gate electrode 124b, and the gate capping layer 126, and the side profiles PF3, PF2, PF2′, and PF1 of the first sub-gate electrode 124a, the second sub-gate electrode 124b, the gate capping layer 126, and the reinforcing insulating layer 122c are briefly described with reference to FIG. 17.

The first sub-gate electrode 124a, the second sub-gate electrode 124b, and the gate capping layer 126 may have the first width W1, the second width W2, and the third width W3, respectively. The third width W3 may be greater than the second width W2, and the second width W2 may be greater than the first width W1.

The first sub-gate electrode 124a, the second sub-gate electrode 124b, and the gate capping layer 126 may have the third sidewall profile PF3, the second sidewall profile PF2′ and the first sidewall profile PF1, respectively. The reinforcing insulating layer 122c may have the expanded second wall profile PF2.

The first sidewall profile PF1 may be curved so that the width of the gate capping layer 126 gradually decreases along the third direction from the upper surface portion of the gate capping layer 126 to the lower surface portion thereof. The second sidewall profile PF2′ may be curved so that the width of the second sub-gate electrode 124b gradually decreases along the third direction from the upper surface portion of the second sub-gate electrode 124b to the lower surface portion thereof.

The expanded second sidewall profile PF2 may be formed outside the second sidewall profile PF2′ by the formation of the reinforcing insulating layer 122c. The expanded second sidewall profile PF2 may be curved so that the width of the reinforcing insulating layer 122c gradually decreases along the third direction from the upper surface portion of the reinforcing insulating layer 122c to the lower surface portion thereof. In the third sidewall profile PF3, the width of the first sub-gate electrode 124a may be substantially equal along the third direction from the upper surface portion of the first sub-gate electrode 124a to the lower surface portion thereof.

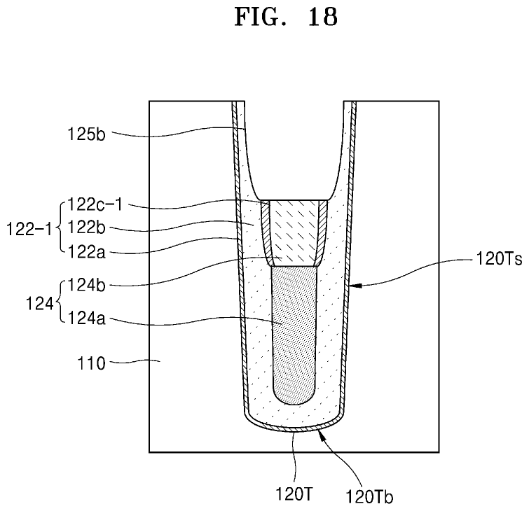

FIG. 18 is a cross-sectional view illustrating a method of manufacturing an IC device, according to an embodiment.

In detail, FIG. 18 may illustrate a method of manufacturing the IC device shown in FIGS. 6 to 8. In FIG. 18, the descriptions given above with reference to FIGS. 6 to 8 are briefly given or omitted.

As described above, the manufacturing process of FIGS. 12 to 15 is performed. As shown in FIG. 15, the base insulating layer 122b is formed in the gate trench 120T, and the gate electrode 124 including the first sub-gate electrode 124a and the second sub-gate electrode 124b may be formed on the base insulating layer 122b. In addition, the second inner hole 125b may be formed on the second sub-gate electrode 124b.

Referring to FIG. 18, the liner insulating layer 122a is formed on the bottom portion 120Tb and the sidewall portion 120Ts of the gate trench 120T, and the reinforcing insulating layer 122c-1 is formed on the sidewall portion of the second sub-gate electrode 124b. The liner insulating layer 122a may be formed simultaneously with the reinforcing insulating layer 122c-1.

The liner insulating layer 122a and the reinforcing insulating layer 122c-1 may be formed by oxidizing or nitrating the bottom portion 120Tb and the sidewall portion 120Ts of the gate trench 120T and the sidewall portion and the upper surface portion of the second sub-gate electrode 124b and then selectively etching an insulating layer formed on the upper surface portion of the second sub-gate electrode 124b. For example, the reinforcing insulating layer 122c-1 may be formed by etching the upper surface portion of the second sub-gate electrode 124b, i.e., the insulating layer exposed by the second inner hole 125b. Through this process, the gate insulating layer 122-1 including the liner insulating layer 122a, the base insulating layer 122b, and the reinforcing insulating layer 122-1 may be formed.

Subsequently, as shown in FIGS. 6 to 8, the gate capping layer 126 filling the second inner hole (125b of FIG. 18) on the second sub-gate electrode 124b is formed. The gate capping layer 126 may be formed by filling the second inner hole (125b of FIG. 18) on the second sub-gate electrode 124b with an insulating layer and then planarizing the insulating layer so that the upper surface of the substrate 110 is exposed. Through this process, the gate electrode structure 127 including the gate electrode 124 and the gate capping layer 126 may be formed as shown in FIGS. 6 to 8.

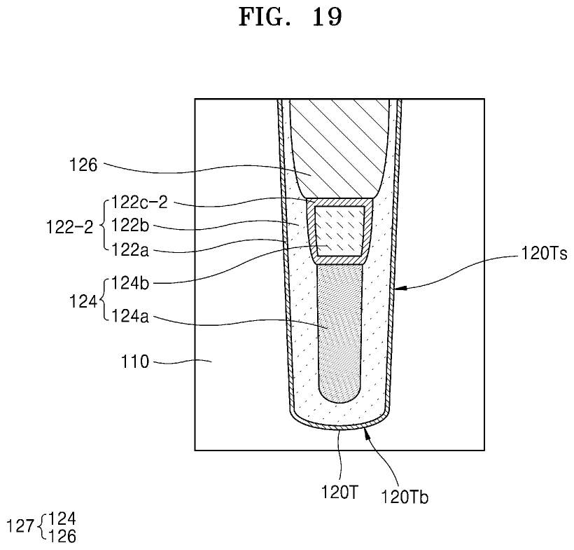

FIG. 19 is a cross-sectional view illustrating a method of manufacturing an IC device, according to an embodiment.

In detail, FIG. 19 may illustrate a method of manufacturing the IC device shown in FIGS. 9 to 11. In FIG. 19, the descriptions given above with reference to FIGS. 9 to 11 are briefly given or omitted.

As described above, the manufacturing process of FIGS. 12 to 15 is performed. As shown in FIG. 15, the base insulating layer 122b is formed in the gate trench 120T, and the gate electrode 124 including the first sub-gate electrode 124a and the second sub-gate electrode 124b may be formed on the base insulating layer 122b. In addition, the second inner hole 125b may be formed on the second sub-gate electrode 124b.

Referring to FIG. 19, the liner insulating layer 122a is formed on the bottom portion 120Tb and the sidewall portion 120Ts of the gate trench 120T, and the reinforcing insulating layer 122c-2 is formed on the sidewall portion, the upper surface portion, and the lower surface portion of the second sub-gate electrode 124b. The liner insulating layer 122a may be formed simultaneously with the reinforcing insulating layer 122c-2.

The liner insulating layer 122a and the reinforcing insulating layer 122c-2 may be formed by oxidizing or nitrating the bottom portion 120Tb and the sidewall portion 120Ts of the gate trench 120T and the sidewall portion, the upper surface portion and the lower surface portion of the second sub-gate electrode 124b. Through this process, the gate insulating layer 122-2 including the liner insulating layer 122a, the base insulating layer 122b, and the reinforcing insulating layer 122-2 may be formed.

Subsequently, the gate capping layer 126 filling the second inner hole (125b of FIG. 15) on the second sub-gate electrode 124b is formed. The gate capping layer 126 may be formed by filling the second inner hole (125b of FIG. 15) on the second sub-gate electrode 124b with an insulating layer and then planarizing the insulating layer so that the upper surface of the substrate 110 is exposed. Through this process, the gate electrode structure 127 including the gate electrode 124 and the gate capping layer 126 may be formed as shown in FIGS. 9 to 11.

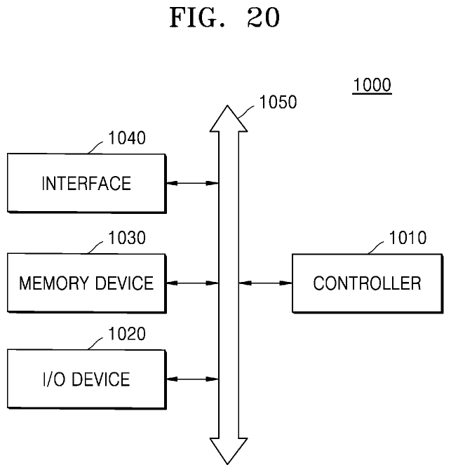

FIG. 20 is a system 1000 including an IC device according to aspects of the inventive concept.

In detail, the system 1000 includes a controller 1010, an input/output (I/O) device 1020, a memory device 1030, and an interface 1040. The system 1000 may be a mobile system or a system transmitting or receiving information.

In some embodiments, the mobile system may include a person digital assistant (PDA), a portable computer, a tablet computer, a wireless phone, a mobile phone, a digital music player, or a memory card.

The controller 1010 is configured to control an execution program in the system 1000 and may include a microprocessor, a digital signal processor, a microcontroller, or a similar device.

The I/O device 1020 may be used to input or output data of the system 1000. The system 1000 may be connected to an external device, such as a personal computer or network using the I/O device 1020, and may exchange data with the external device. The I/O device 1020 may include, for example, a keypad, a keyboard, or a display.

The memory device 1030 may store code and/or data for the operation of the controller 1010, or store the data processed by the controller 1010. The memory device 1030 may include the IC device 100 according to an embodiment.

The interface 1040 may be a data transfer passage between the system 1000 and other devices. The controller 1010, the I/O device 1020, the memory device 1030, and the interface 1040 may communicate with each other through a bus 1050.

The system 1000 may be used in mobile phones, MP3 players, navigation devices, portable multimedia players (PMPs), solid state disks (SSDs), or household appliances.

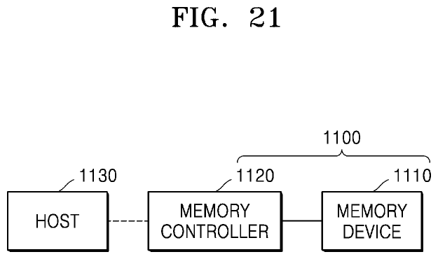

FIG. 21 is a memory card 1100 including a semiconductor device according to aspects of the inventive concept.

Specifically, the memory card 1100 includes a memory device 1110 and a memory controller 1120. The memory device 1110 may store data. In some embodiments, the memory device 1110 may have non-volatile characteristics that may maintain stored data even if power supply is interrupted. The memory device 1110 may include the IC device 100 according to an embodiment.

The memory controller 1120 may read data stored in the memory device 1110 in response to the read/write request of the host 1130, or store the data of the memory device 1110. The memory controller 1120 may include the IC device 100 according to an embodiment.

The IC device according to aspects of the inventive concept may include a gate insulating layer including a reinforcing insulating layer formed on a sidewall portion of a gate electrode including a plurality of sub-gate electrodes. Accordingly, in the IC device according to aspects of the inventive concept, reliability of the gate insulating layer may be improved due to the reinforcing insulating layer.

While aspects of the inventive concept have been particularly shown and described with reference to embodiments thereof, it will be understood that various changes in form and details may be made therein without departing from the spirit and scope of the following claims.

What is claimed is:

1. An integrated circuit (IC) device comprising:
a gate trench formed inside a substrate, the gate trench including a bottom portion and a sidewall portion;
a gate electrode structure disposed apart from the bottom portion and the sidewall portion of the gate trench, the gate electrode structure including a gate electrode and a gate capping layer, the gate electrode including a first sub-gate electrode formed in a lower portion of the gate trench and a second sub-gate electrode formed on the first sub-gate electrode, the gate capping layer being formed on the second sub-gate electrode; and
a gate insulating layer formed between the gate trench and the gate electrode structure, the gate insulating layer including a base insulating layer and a reinforcing insulating layer, the base insulating layer being formed between the bottom portion and the sidewall portion of the gate trench and the gate electrode structure, and the reinforcing insulating layer being formed on a sidewall portion of the second sub-gate electrode.

2. The IC device of claim 1, wherein the first sub-gate electrode includes a metal layer,
the second sub-gate electrode includes a polysilicon layer doped with impurities, and
the reinforcing insulating layer may include a silicon oxide layer.

3. The IC device of claim 1, wherein the reinforcing insulating layer further includes an upper surface reinforcing insulating layer formed on an upper surface portion of the second sub-gate electrode.

4. The IC device of claim 3, wherein the reinforcing insulating layer further includes a lower surface reinforcing insulating layer formed on a lower surface portion of the second sub-gate electrode.

5. The IC device of claim 1, wherein the gate insulating layer further includes a liner insulating layer formed on the bottom portion and the sidewall portion of the gate trench.

6. The IC device of claim 1, wherein a third width at a middle level of the gate capping layer is greater than a second width at a middle level of the second sub-gate electrode.

7. The IC device of claim 1, wherein a second width at a middle level of the second sub-gate electrode is greater than a first width at a middle level of the first sub-gate electrode.

8. The IC device of claim 1, wherein a sidewall profile of the gate capping layer is curved so that a width of the gate capping layer gradually decreases along a direction from an upper surface portion of the gate capping layer to a lower surface portion of the gate capping layer.

9. The IC device of claim 1, wherein a sidewall profile of the second sub-gate electrode is curved so that a width of the second sub-gate electrode gradually decreases along a direction from an upper surface portion of the second sub-gate electrode to a lower surface portion of the second sub-gate electrode.

10. The IC device of claim 1, wherein a thickness of an upper sidewall of the reinforcing insulating layer formed on an upper sidewall portion of the second sub-gate electrode is greater than a thickness of a lower sidewall of the reinforcing insulating layer formed on the lower sidewall portion of the second sub-gate electrode.

11. An integrated circuit (IC) device comprising:
a gate trench formed inside a substrate, the gate trench including a bottom portion and a sidewall portion;
a gate electrode structure disposed apart from the bottom portion and the sidewall portion of the gate trench inside the gate trench, the gate electrode structure including a gate electrode and a gate capping layer, the gate electrode including a first sub-gate electrode formed in a lower portion of the gate trench and a second sub-gate electrode formed on the first sub-gate electrode, the gate capping layer being formed on the second sub-gate electrode; and
a gate insulating layer formed between the gate trench and the gate electrode structure, the gate insulating layer including a base insulating layer and a reinforcing insulating layer, the base insulating layer being formed between the bottom portion and the sidewall portion of the gate trench and the gate electrode structure, and the reinforcing insulating layer being formed on a sidewall portion of the second sub-gate electrode,
wherein a second thickness of the gate insulating layer between the sidewall portion of the second sub-gate electrode and the sidewall of the gate trench on a top level of the second sub-gate electrode is greater than a first thickness of the gate insulating layer between the sidewall portion of the gate capping layer and the sidewall portion of the gate trench on a bottom level of the gate capping layer.

12. The IC device of claim 11, wherein a fourth thickness of the gate insulating layer between the sidewall portion of the second sub-gate electrode and the sidewall portion of the gate trench on a bottom level of the second sub-gate electrode is greater than a third thickness of the gate insulating layer between the sidewall portion of the first sub-gate electrode and the sidewall portion of the gate trench on a top level of the first sub-gate electrode.

13. The IC device of claim 11, wherein the first sub-gate electrode includes a metal layer, and the second sub-gate electrode includes a polysilicon layer doped with impurities.

14. The IC device of claim 11, wherein the reinforcing insulating layer further includes an upper surface reinforcing insulating layer formed on an upper surface portion of the second sub-gate electrode.

15. The IC device of claim 11, wherein the reinforcing insulating layer further includes a lower surface reinforcing insulating layer formed on a lower surface portion of the second sub-gate electrode.

16. The IC device of claim 11, wherein a thickness of an upper sidewall of the reinforcing insulating layer formed on an upper sidewall portion of the second sub-gate electrode is greater than a thickness of a lower sidewall of the reinforcing insulating layer formed on the lower sidewall portion of the second sub-gate electrode.

17. An integrated circuit (IC) device comprising:
a gate trench formed inside a substrate, the gate trench including a bottom portion and a sidewall portion;
a gate electrode structure disposed apart from the bottom portion and the sidewall portion of the gate trench inside the gate trench, the gate electrode structure including a gate electrode including a first sub-gate electrode formed in a lower portion of the gate trench and including a metal layer, and a second sub-gate electrode formed on the first sub-gate electrode and including a polysilicon layer doped with impurities, and a gate capping layer formed on the second sub-gate electrode; and
a gate insulating layer formed between the gate trench and the gate electrode structure, the gate insulating layer including a liner insulating layer formed on the bottom portion and the sidewall portion of the gate trench and including a silicon oxide layer, a base insulating layer formed between the liner insulating layer and the gate electrode structure, and a reinforcing insulating layer formed on the sidewall portion of the second sub-gate electrode and including a silicon oxide layer,
wherein a second thickness of the reinforcing insulating layer and the base insulating layer formed on the sidewall portion of the second sub-gate electrode on a top level of the second sub-gate electrode is greater than a first thickness of the base insulating layer formed on the sidewall portion of the gate capping layer on a bottom level of the gate capping layer.

18. The IC device of claim 17, wherein the reinforcing insulating layer is further formed on an upper surface portion of the second sub-gate electrode to surround an upper corner of the second sub-gate electrode.

19. The IC device of claim 17, wherein a fourth thickness of the reinforcing insulating layer and the base insulating layer formed on the sidewall portion of the second sub-gate electrode on a bottom level of the second sub-gate electrode is greater than a third thickness of the base insulating layer formed on the sidewall portion of the first sub-gate electrode on a top level of the first sub-gate electrode.

20. The IC device of claim 17, wherein a third width at a middle level of the gate capping layer is greater than a second width at a middle level of the second sub-gate electrode,
the second width at the middle level of the second sub-gate electrode is greater than a first width at a middle level of the first sub-gate electrode,
a sidewall profile of the gate capping layer is curved so that a width of the gate capping layer gradually decreases along a direction from an upper surface portion of the gate capping layer to a lower surface portion of the gate capping layer, and
a sidewall profile of the second sub-gate electrode is curved so that a width of the second sub-gate electrode gradually decreases along a direction from an upper surface portion of the second sub-gate electrode to a lower surface portion of the second sub-gate electrode.
